(19) United States
(12) Patent Application Publication
(10) Pub. No.: US 2010/0112494 A1
(43) Pub. Date: May 6, 2010

(54) APPARATUS AND METHOD FOR MEASURING THE OUTGASSING AND EUV LITHOGRAPHY APPARATUS

(75) Inventors: Dieter Kraus, Oberkochen (DE); Dirk Heinrich Ehm, Lauchheim (DE); Theodoor Bastiaan Wolschrijn, Abcoude (NL); Johannes Hubertus Josephina Moors, Helmond (NL)

Correspondence Address: DARBY & DARBY P.C., P.O. BOX 770, Church Street Station, New York, NY, 10008-0770, US

(73) Assignees: Carl Zeiss SMT AG, Oberkochen (DE); ASML Netherlands B.V, Veldhoven (NL)

(21) Appl. No.: 12/552,483

(22) Filed: Sep. 2, 2009

Related U.S. Application Data
(63) Continuation of application No. PCT/EP2008/001643, filed on Mar. 3, 2008.

(30) Foreign Application Priority Data
Mar. 7, 2007 (DE) 10 2007 011 482.8

(51) Int. Cl. G03F 7/20; G03B 27/54

(52) U.S. Cl. 430/322; 355/67

(57) ABSTRACT

An apparatus and method for measuring an outgassing in a EUV lithography apparatus. The method includes activating a surface within the EUV lithography apparatus, inducing the outgassing, analyzing a residual gas. Defining a maximum partial pressure, recording a mass spectrum of the residual gas, converting the highest-intensity peaks of the mass spectrum into sub-partial pressures, summing the sub-partial pressures, and comparing the summed result with the defined maximum partial pressure. An EUV lithography apparatus includes a residual gas analyzer and a stimulation unit comprised of at least on of an electron source, an ion source, a photon source, and a plasma source. A measurement setup for measuring the outgassing from components by analyzing the residual gas includes a residual gas analyzer, a vacuum chamber, and a stimulation unit comprised of at least on of an electron source, an ion source, a photon source, and a plasma source.

### CLAIM OF PRIORITY

This application is a continuation, and claims priority under 35 U.S.C. §365, of International Application No. PCT/EP2008/001643, filed on Mar. 3, 2008, and claims the benefit of priority of German Patent Application No. 10 2007 011 482.8, filed Mar. 7, 2007, the disclosures of each are hereby incorporated by reference in their entireties. The International Application was published in German on Sep. 12, 2008 as WO2008/107136.

### FIELD

The present invention relates to an apparatus and a method for measuring the outgassing in extreme ultraviolet (EUV) lithography systems having an illumination and a projection system, and in particular to measuring the outgassing from components by analyzing the residual gas.

### BACKGROUND

In EUV lithography apparatus, reflective optical elements for the extreme ultraviolet and soft X-ray wavelength range (e.g., wavelengths of between approximately 5 nm and 20 nm) such as photomasks or multilayer mirrors, for instance, are used for the lithography of semiconductor components. Since EUV lithography apparatus generally have a plurality of reflective optical elements, the latter have to have the highest possible reflectivity in order to ensure a sufficiently high total reflectivity. The reflectivity and the lifetime of the reflective optical elements can be reduced by contamination of the optically utilized reflective area of the reflective optical elements, which arises on account of the short-wave irradiation together with residual gases in the operating atmosphere. Since a plurality of reflective optical elements are usually arranged one behind another in an EUV lithography apparatus, even relatively small amounts of contamination on each individual reflective optical element affect the total reflectivity to a relatively large extent.

In order to decide whether an EUV lithography apparatus can be put into operation, inter alia the outgassing is measured by residual gas analysis. For this purpose, the EUV lithography apparatus is usually evacuated for several hours at room temperature until a sufficient vacuum for the use of commercially available residual gas analyzers has been achieved, and then the residual gas analysis is carried out likewise at room temperature. This procedure is important particularly in the case of EUV lithography apparatus which cannot be overly heated, e.g. because the geometrical and optical tolerances in the case of optical components and the holders thereof are so narrow that even heating the EUV lithography apparatus would have an adverse effect thereon because limit temperatures of the optical components, in particular of multilayer mirrors, would be exceeded.

### SUMMARY

In one embodiment, the present invention provides a method for measuring an outgassing in a EUV lithography apparatus. The method includes activating a surface within the EUV lithography apparatus, inducing the outgassing, analyzing a residual gas, defining a maximum partial pressure, recording a mass spectrum of the residual gas, converting the highest-intensity peaks of the mass spectrum which can be assigned to the specific chemical compound into sub-partial pressures, summing the sub-partial pressures, and comparing the summed result with the defined maximum partial pressure.

In another embodiment, the invention provides an EUV lithography apparatus, which includes a stimulation unit comprised of at least one of an electron source, an ion source, a photon source, and a plasma source. The EUV lithography apparatus also includes a residual gas analyzer. Wherein the stimulation unit is configured to induce outgassing by exposing a surface within the EUV lithography apparatus to an output of the stimulation unit, and wherein the residual gas analyzer is configured to analyze the induced outgassing.

In yet another embodiment, the invention provides a measurement setup for measuring the outgassing from components by analyzing the residual gas. The measurement setup including a stimulation unit comprised of at least one of an electron source, an ion source, a photon source, and a plasma source. The measurement setup also includes a residual gas analyzer and a vacuum chamber, wherein the stimulation unit and the residual gas analyzer are within the vacuum chamber, and the stimulation unit is configured to induce outgassing by exposing a surface within the EUV lithography apparatus to an output of the stimulation unit, and wherein the residual gas analyzer is configured to analyze the induced outgassing.

### BRIEF DESCRIPTION OF THE FIGURES

FIG. 1 schematically illustrates a EUV lithography apparatus in accordance with an embodiment of the present invention;

FIG. 2 depicts a flowchart of a method for measuring outgassing in accordance with an embodiment of the present invention;

FIG. 3 depicts a flowchart of a method for measuring outgassing in accordance with another embodiment of the present invention;

FIG. 4 depicts a flow chart of a method for measuring the outgassing in accordance with another embodiment of the present invention; and

FIG. 5 schematically illustrates a measurement setup in accordance with an embodiment of the present invention.

### DESCRIPTION

Embodiments of the present invention provide an apparatus and method for measuring the outgassing in EUV vacuum systems, in particular in EUV lithography apparatus, by analyzing the residual gas.

In one embodiment, a method measures the outgassing in EUV lithography apparatus by analyzing the residual gas, in which the outgassing is induced before the residual gas is analyzed by activating a surface within the EUV apparatus.

Under this method even low-volatility compounds, in particular low-volatility hydrocarbons, to be detected. Specifically, it has been found that even low-volatility hydrocarbons also have a non-negligible influence on the contamination of the optical components when operation of an EUV lithography apparatus is started, but they are not detected in the conventional method. Thus, on the basis of the residual gas analysis, EUV lithography apparatus have hitherto been cleared for operation but said apparatus have nevertheless led to unacceptable contamination during the exposure process on account of desorption of, in particular, low-volatility hydrocarbons that is induced by photons or secondary electrons. What is achieved by inducing outgassing for the residual gas analysis by surface activation is that even low-volatility hydrocarbons are present in the residual gas in a concentration which lies above the detection limit of conventional residual gas analyzers. Consequently, the sensitivity of the residual gas analysis is effectively increased by means of the method proposed. What is thereby achieved is that it is possible to forecast much more accurately whether the interior of an EUV lithography apparatus is clean enough to be able to start operation without having to fear excessively high contamination.

An embodiment of the present invention provides a EUV lithography apparatus with an electron source, ion source, photon source or plasma source as a stimulation unit and further includes a residual gas analyzer, and also an illumination system. Another EUV lithography apparatus has an electron source, ion source, photon source or plasma source as stimulation unit and a residual gas analyzer, and a projection system.

It is thus possible that the contamination of low-volatility compounds which can contribute to the contamination and which have deposited on surfaces within the vacuum systems can be converted into the gas phase by activation of the surfaces (through exposure to photons, electrons, neutral particles, etc.), and then be detected by a residual gas analyzer.

In another embodiment, the invention provides a measurement setup for measuring outgassing from components by analyzing the residual gas, in which an electron source, ion source, photon source or plasma source as stimulation unit and a residual gas analyzer are arranged in a vacuum chamber. A method for measuring the outgassing from components by analyzing the residual gas, in which, in a vacuum chamber, a surface of a component is activated (through exposure to photons, electrons, neutral particles, etc.), in order to induce outgassing, and the residual gas in the vacuum chamber is analyzed.

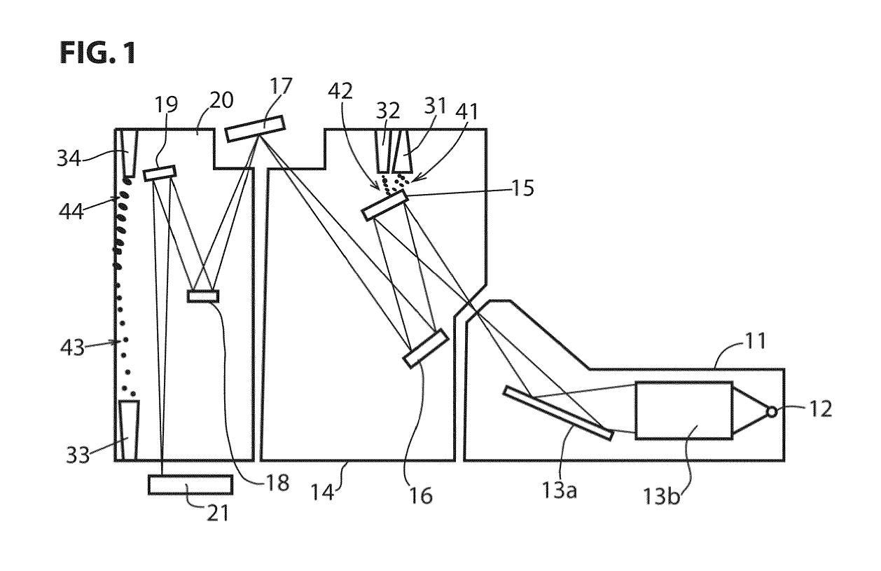

FIG. 1 schematically illustrates an EUV lithography apparatus 10. Components of lithography apparatus 10 include the beam shaping system 11, the illumination system 14, the photomask 17 and the projection system 20. The EUV lithography apparatus 10 is operated under, or as close as possible to, vacuum conditions in order that the EUV radiation is absorbed as little as possible in its interior. The EUV lithography apparatus 10 can also be regarded as an EUV vacuum system in this sense. The vacuum system can also be subdivided. For this purpose, individual components such as, for example, the illumination system 14 and the projection system 20, or the beam shaping system 11 can be configured as vacuum systems that are independent of one another at least to an extent such that the vacuum can be adapted to the conditions that are different, if appropriate, in different components. The subdivision with regard to the vacuum may additionally permit a faster evacuation of the EUV lithography apparatus at the beginning of operation being started.

By way of example, a plasma source or alternatively a synchrotron can serve as radiation source 12. The emerging radiation in the wavelength range of approximately 5 nm to 20 nm is first concentrated in the collimator 13b. In addition, the desired operating wavelength is filtered out with the aid of a monochromator 13a by the variation of the angle of incidence. In the wavelength range stated, the collimator 13b and the monochromator 13a are usually embodied as reflective optical elements. Collimators are often reflective optical elements embodied in a shell-shaped manner in order to achieve a focussing or collimating effect. The reflection of the radiation takes place at the concave area, where it is often the case that a multilayer system is not used on the concave area for reflection purposes, since a broadest possible wavelength range is intended to be reflected. The filtering-out of a narrow wavelength band by reflection takes place at the monochromator, often with the aid of a grating structure or a multilayer system.

The operating beam conditioned with regard to wavelength and spatial distribution in the beam shaping system 11 is then introduced into the illumination system 14. In the example illustrated in FIG. 1, the illumination system 14 has two mirrors 15, 16. The mirrors 15, 16 direct the beam onto the photomask 17, which has the structure that is intended to be imaged onto the wafer 21. The photomask 17 is likewise a reflective optical element for the EUV and soft wavelength range, which is exchanged depending on the production process. With the aid of the projection system 20, the beam reflected from the photomask 17 is projected onto the wafer 21 and the structure of the photomask is thereby imaged onto said wafer. In the example illustrated, the projection system 20 has two mirrors 18, 19. It should be pointed out that both the projection system 20 and the illumination system 14 can in each case have just one or alternatively three, four, five or more mirrors.

The EUV or soft X-ray radiation itself, or the photoelectrons or secondary electrons generated by the irradiation, already leads to a small extent to the disassociation of hydrocarbon compounds, in particular including low-volatility hydrocarbon compounds, into smaller carbon-containing molecules, which can deposit as contamination on the optically utilized area of the reflective optical elements and thereby reduce the reflectivity thereof. On account of these processes, the radiation source 12 itself can be used as a stimulation unit using photons and/or secondary electrons.

The EUV lithography apparatus 10 illustrated in FIG. 1 has, both in the illumination system 14 and in the projection system 20, a stimulation unit 32, 34 and a residual gas analyzer 31, 33, in order, before the start of operation, with the aid of the stimulation units 32, 34, to induce outgassing within the illumination system 14 and the projection system 20, respectively, and to carry out a more comprehensive residual gas analysis including with regard to low-volatility hydrocarbons. For even small quantities of low-volatility hydrocarbons are already able to impair the reflectivity of the optical elements such as the mirrors 15, 16, 18, 19, for instance, if they undergo transition to the gas phase as a result of scattered light and deposit on the optical elements. The increase in contaminating substances in the gas phase during the first hours of irradiation with EUV or soft X-ray radiation in a new EUV lithography apparatus, initiated by direct or indirect irradiation of vacuum components, contaminates the optical elements with carbon layers, as a result of which the reflectivity thereof decreases.

The following are appropriate for inducing the outgassing: irradiation with higher-energy electromagnetic irradiation, or else bombardment with charged or neutral particles, inter alia also by introducing a plasma. The contaminating material is induced to outgas (i.e., vaporize) by the irradiation or the bombardment. Different methods for inducing the outgassing can, as required, also be combined with one another and be performed simultaneously or successively. As a result of irradiation with photons having any desired wavelength and/or bombardment of relatively large surfaces within a vacuum chamber or in a targeted manner at locations where there is no need to fear impairment of components already incorporated, the molecules present at the surface are fed energy that leads to a desorption even of low-volatility compounds, with the result that they accumulate in the residual gas atmosphere to an extent such that they can be detected by residual gas analyzers. In this case, residual gas analyzers in any desired number and of a wide variety of types can be used, inter alia with a quadrupole magnet as mass filter, on the basis of a cyclotron or a resonator ring, and many more besides.

The targeted stimulation of contaminants in the vicinity of optical components is advantageous since these regions are particularly jeopardized by scattered light and secondary electrons that occur during the exposure process. Particular preference is given to stimulation by irradiation with photons in the EUV or soft X-ray wavelength range, in order to achieve outgassing conditions that are as realistic as possible, or by scanning surfaces with an electron beam, in order to detach low-volatility contaminants from the surface and to convert them into the gas phase. With an electron beam this can be carried out in a targeted and locally delimited manner with high precision. An ion beam is also suitable instead of an electron beam. Since even low-volatility contaminants are converted into the gas phase by means of the stimulation, the detection sensitivity of the residual gas analysis is increased by a multiple and the measurement of the outgassing is correspondingly improved.

In the example illustrated in FIG. 1, the outgassing in the illumination system 14 is induced with the aid of electrons 42. Photons 44 in the EUV to soft X-ray wavelength range are used in the projection system 20. Both variants provide for activating a specific area in a targeted manner.

In the illumination system 14, the electron gun 32 is arranged in such a way that an area at the edge of the mirror 15 is activated in a targeted manner, such as, for instance, a surface of the mirror holder (not illustrated in detail). The residual gas analyzer 31 is arranged in such a way that its measuring head is situated as near as possible to the location at which the electron beam 42 impinges on the surface, in order that as far as possible all particles 41 which desorb on account of the energy input by the electrons and undergo transition to the gas phase are detected by the residual gas analyzer 31. In some instances, in particular relatively long-chain molecules are also dissociated into smaller parts. In addition, in the arrangement care was taken to ensure that neither the electron gun 32 nor the residual gas analyzer 31 projects into the beam path during operation of the EUV lithography apparatus 10. One advantage of using electrons is that, with the aid of electromagnetic fields, the electrons can be focused very accurately onto any desired areas including those having only a small size. Thus, within the illumination system, the surface could be activated at virtually all locations in the manner of random sampling and outgassing could thereby be induced locally and the resultant residual gas could be examined for low-volatility compounds that could contribute to contamination. Surfaces which are exposed to scattered radiation during operation of the EUV lithography apparatus 10 are activated in this case, as shown by way of example in FIG. 1. However, surfaces which are exposed to direct radiation or no radiation during operation can also be activated. The electron gun 32 can also be replaced by an ion source.

In the projection system 20, by contrast, in the example illustrated in FIG. 1, an EUV or soft X-ray source 34 is employed for surface activation, in order to activate an area of the side wall of the vacuum chamber of the projection system 20 with a larger area and to desorb the low-volatility compounds deposited there. Owing to their not inconsiderable energy, the photons 44 lead not only to a desorption but also to a dissociation of, in particular, relatively long-chain molecules into smaller units which are likewise associated with the residual gas components 43 of the resultant residual gas and are analyzed by the residual gas analyzer 33. By using photons in the same energy range as the operating radiation, it is possible to simulate particularly well the outgassing when operation is started, with the result that a particularly accurate estimation of the current risk of contamination can be carried out on the basis of the residual gas components found and on the basis of their partial pressures.

In the case of EUV lithography apparatus which have low thermal tolerances and cannot be overly heated, for example, the intensity of the photon beam 44 or of the electron beam is set such that undesired heating does not take place.

The present invention contemplates that any desired methods for inducing outgassing can be used as required not just in the illumination system 14 or the projection system 20. In particular, it is equally well possible to employ photons in the illumination system 14 or electrons or ions in the projection system 20. Likewise, the surfaces to be activated can also be exposed to a plasma or bombardment with neutral particles and a plurality of methods for inducing outgassing can also be combined with one another. For this purpose, the electron gun 32 or the X-ray source 34 can be replaced by ion sources or plasma sources. The electron gun 32 and the X-ray source 34 are likewise interchangeable with respect to one another. Moreover, electron guns, X-ray sources, ion sources and plasma sources can be provided in any desired number and combination in order to carry out surface activations one after another or simultaneously by bombardment with high-energy photons or charged or uncharged particles. In this case, it is possible to activate just one or else a plurality of surfaces within the EUV lithography apparatus 10. Depending on the conditions within the specific EUV lithography apparatus 10, in this case it is also possible to carry out different activations on different surfaces.

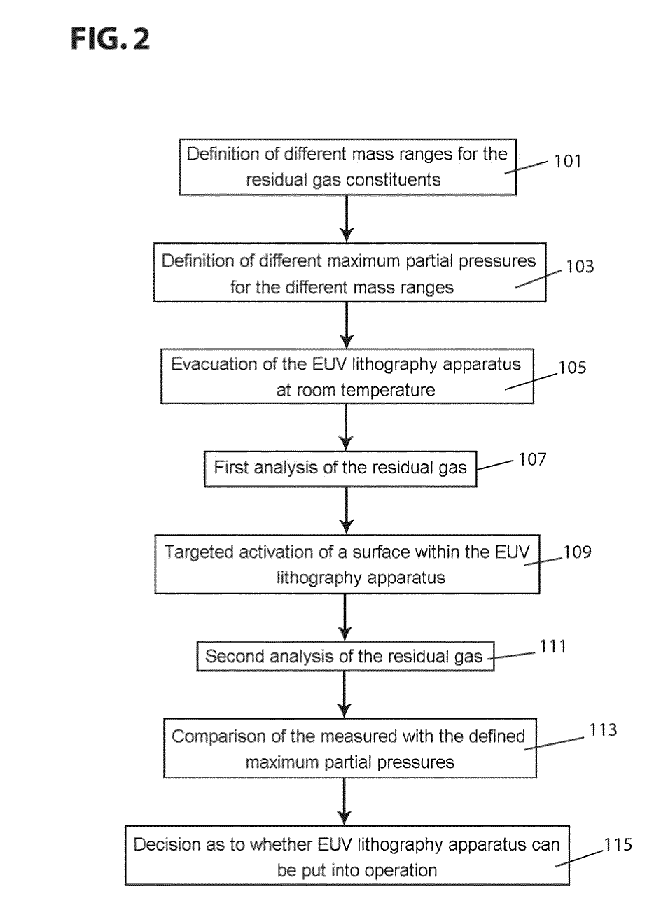

The sequence of a first embodiment of the method for measuring the outgassing is illustrated in a flowchart in FIG. 2. First, different mass ranges are defined for the residual gas constituents (step 101) and different maximum partial pressures are defined for these mass ranges (step 103). By way of example, the following mass ranges could be chosen: 45-100 amu (atomic mass unit), 101-150 amu, 151-200 amu. Atoms, molecules or molecular fragments within a vacuum system with masses of less than 45 amu are generally volatile and are already detected in residual gas analyses without induced outgassing. It is also possible, as required, to define further ranges for higher masses, e.g. 201-300 amu or higher. In the mass ranges stated, e.g. the following maximum partial pressures could be defined: 1.0·10⁻⁹ mbar for the range 45-100 amu, 5.0·10⁻¹² mbar for the range 101-150 amu and 5.0·10′⁻¹³ mbar for the range 151-200 amu. Here it was taken into consideration, in particular, that the sensitivity of conventional residual gas analyzers, which are usually based on mass spectrometers, decreases exponentially with increasing masses. The concrete mass ranges and maximum partial pressures for a specific vacuum environment are best determined experimentally in preparatory tests.

In a subsequent step 105, the vacuum system, for example that of an EUV lithography apparatus, is evacuated at room temperature for a few hours until a sufficient vacuum has been achieved in order to be able to use a residual gas analyzer. This can take up to 10 hours or longer in the case of EUV lithography apparatus. In order to obtain a first estimation of the residual gas and of the outgassing effected, a first analysis of the residual gas is carried out in this state (step 107). The results may already be so poor in this measurement that an additional cleaning of the vacuum system appears to be required, if the maximum partial pressure is exceeded e.g. particularly in the range with the lowest masses. In order to determine the partial pressure within a mass range, all the partial pressures within this mass range are summed. After a successful first measurement, a surface within the vacuum system. e.g. an EUV lithography apparatus, is activated in a targeted manner (step 109). A possibility for inducing outgassing consists in activating surfaces within the vacuum systems, for example, by means of photons, electrons or ion plasma or ions, in order to convert the low-volatility substances from the surface into the gas phase.

After the outgassing has been induced by surface activation, the second residual gas analysis can be carried out (step 111), in which even low-volatility compounds possibly present, in particular low-volatility hydrocarbons that cause contamination, should now have undergone transition to the gas phase and can be detected by the residual gas analysis. Through summation of all the partial pressures within a respective mass range, it is possible to determine the partial pressure for each mass range and then to compare it with the defined maximum permissible partial pressures (step 113). The result of this comparison serves as a basis for a decision as to whether, in the present example, the EUV lithography apparatus can be cleared for operation (step 115) or cleaning additionally has to be carried out, A different cleaning can possibly be carried out depending on the mass range in which the maximum partial pressure was exceeded.

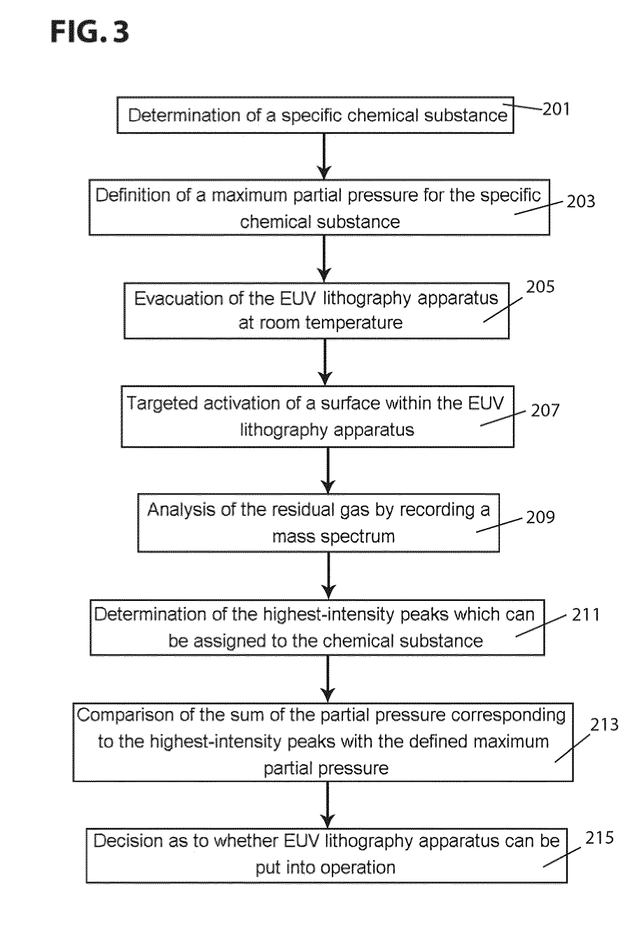

The sequence of a second embodiment of the method for measuring the outgassing is illustrated in a flowchart in FIG. 3. The approach followed here involves first identifying a chemical compound specifically as particularly hazardous for contamination when operation is started (step 201), and then defining a specific maximum permissible partial pressure for said chemical compound (step 203). Within EUV lithography apparatus, such a substance is for example Fomblin®, a perfluoropolyether lubricant.

The vacuum system such as an EUV lithography apparatus, for instance, is evacuated (step 205) at room temperature until a sufficient vacuum for the use of a residual gas analyzer has been achieved. Afterward, through targeted activation of a surface within the vacuum system, an outgassing even of low-volatility compounds is induced (step 207) and the residual gas is analyzed by recording a mass spectrum (step 209). The intensity of the peaks which can be assigned to the chemical compound is determined in the mass spectrum (step 211). In the case of Fomblin for example, a compound which is used as a lubricant in vacuum pumps, these are the peaks at 68, 100, 119, 101, 150, 151 amu. The partial pressures corresponding to the peak intensities are summed and compared with the defined specific maximum partial pressure (step 213). In order to reduce the measurement and evaluation complexity, it is also possible to implement restriction to the highest-intensity peaks. In the case of Fomblin, the four peaks at 68, 119, 100 (E and 150 amu would be chosen, by way of example. Depending on whether or not the maximum partial pressure is exceeded, in the present case the EUV lithography apparatus can be put into operation or it has to be additionally cleaned (step 215).

In this method variant, too, it should be pointed out that the definition of compounds which are harmful for EUV optics and also their partial pressures should be determined experimentally in a specific irradiation test of the EUV optics and the respective ambient conditions.

In both of the exemplary method sequences described here it holds true that, in particular, if small areas are locally activated, the activation and the subsequent measurement are advantageously repeated in the manner of random sampling for different locations within the EUV vacuum system before a decision is taken about clearance or renewed cleaning. In particular, surfaces of specific vacuum components can be activated in a targeted manner in order to take a decision about the use thereof in EUV lithography apparatus.

The two method sequences described here can also be combined with one another. Through the choice of specific mass ranges or specific chemical compounds and their highest-intensity peaks, it is possible, on the one hand, to reduce the measurement and evaluation complexity and, on the other hand, to achieve a certain standardization of the measurement and thus also substantial automation. In the context of automation, the activation, the measurement and/or the evaluation thereof can be performed by a control unit, such as a computer, for instance. As soon as one set of parameters has been determined, such as mass ranges or specific mass peaks, for a specific type for example of an EUV lithography apparatus in a specific operating environment, it can be estimated whether this EUV lithography apparatus has a concrete risk of contamination according to a uniform scale. The definition of outgassing rates in future lithography systems can also be facilitated by the method proposed.

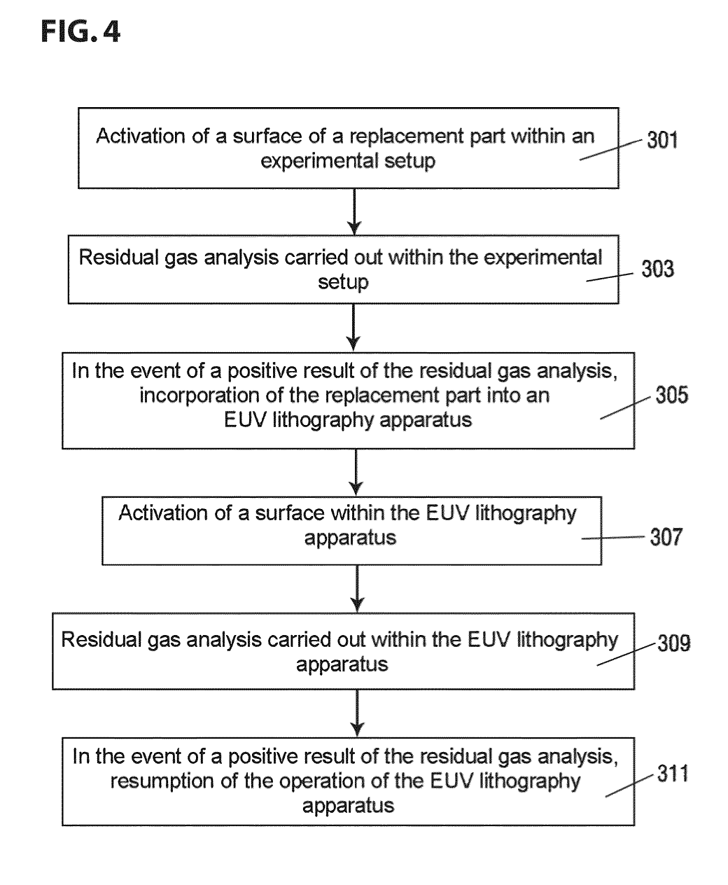

FIG. 4 illustrates a further embodiment of the method for measuring the outgassing. In the context of a preparatory measurement, within an experimental setup in the form of a vacuum system made available especially for this purpose, the surface of a replacement part is activated in a manner described above (step 301). A residual gas analysis in the form already, described is thereupon carried out within the experimental setup (step 303). If the residual gas analysis yields a positive result to the effect that previously defined limit values for the global outgassing, the outgassing in specific mass ranges or the outgassing of specific chemical compounds are not exceeded, this replacement part which has been tested in this way can be incorporated into an EUV lithography apparatus (step 305). Once the previously tested replacement part has been incorporated into the EUV lithography apparatus, the outgassing is measured anew within the EUV lithography apparatus. For this purpose, a surface within the EUV lithography apparatus is activated (step 307) and a residual gas analysis is carried out within the EUV lithography apparatus (step 309). If the result of the residual gas analysis proves to be positive, the operation of the EUV lithography apparatus can be resumed after the replacement part has been incorporated (step 311).

If the residual gas analysis proves to be negative, additional cleaning steps are necessary. In the event of a negative result of the residual gas analysis within the experimental setup, the replacement part should be cleaned again or another replacement part should be chosen. It may be necessary to choose a replacement part composed of a material exhibiting less outgassing.

The replacement part can be any desired component, such as e.g. optical elements or cables or vacuum components. In this case, these elements may have been exchanged or repaired or completely newly introduced into the EUV lithography apparatus.

Particularly, a residual gas analysis after activation of the surface is carried out not just after a change of components within the EUV lithography apparatus in the context of maintenance, repair or installation, rather the outgassing is also already measured beforehand by activating the surface and carrying out a residual gas analysis. By comparing the measurements before and after the change, it is possible to better assess the influence as a result of the change introduced.

The method described here for measuring the outgassing can be carried out both before the initial start-up of an EUV lithography apparatus and in pauses in operation after their maintenance, repair or change work as a result of the introduction of new components. Areas that may be exposed to scattered light during operation are activated in this case. For it is at these areas that the risk of unforeseen outgassings occurring during operation is the highest. Said outgassings could otherwise have a contaminating effect on the optical elements.

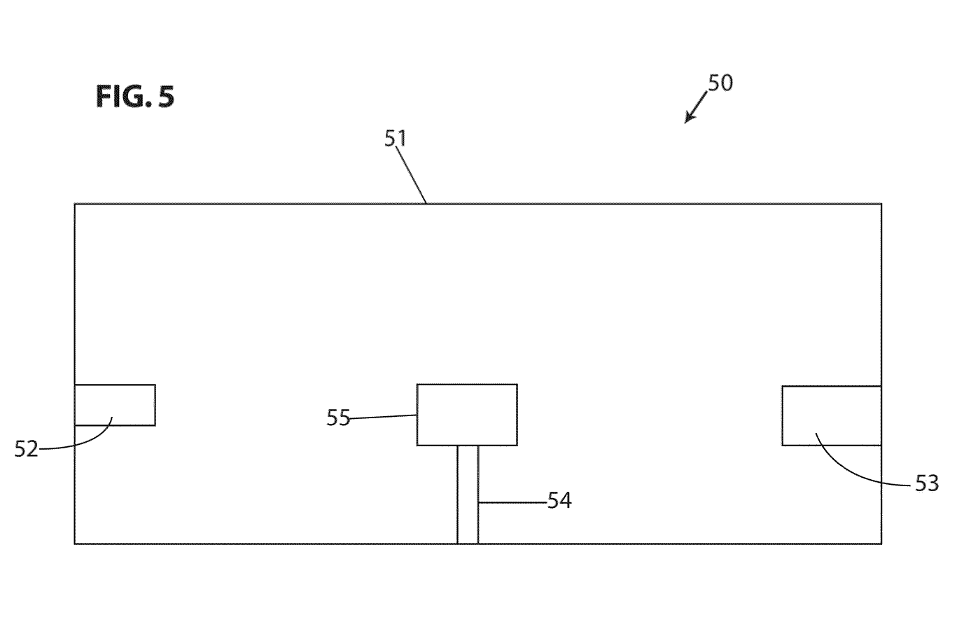

A measurement setup 50 is illustrated by the example in FIG. 5. A stimulation unit 52 for activating the surface of a component 55 and also an arbitrary residual gas analyzer 53 are provided in a vacuum chamber 51.

The stimulation unit 52 can be an electron source, an ion source, a photon source or a plasma source, wherein a plurality of sources, also of different types, can also be combined with one another. The choice of source, depends, inter alia, on the extent of the surface area, the intensity and the energy of the desired surface activation.

The residual gas atmosphere within the vacuum chamber 51 is already analyzed prior to the introduction of the component 55, in order to ascertain possible outgassings from the component 55 by means of differential measurements. Prior to the surface activation, too, the residual gas atmosphere should be analyzed in order to ascertain whether the component 55 is not already outgassing without surface activation. For the residual gas analysis, a sufficiently good vacuum is set in order to be able to operate the residual gas analyzer 53. Many residual gas analyzers require a vacuum in the range of approximately 10⁻⁵ to 10⁻⁷ mbar.

In the example illustrated in FIG. 5, the component 55 is held by a manipulated holder 54 that permits the component 55 to be displaced and/or rotated or tilted in the vacuum chamber 51, in order to be able to activate as far as possible any desired surfaces of the component. After the surface activation by means of electromagnetic radiation, charged or neutral particles, the residual gas atmosphere then established is once again analyzed in order to ascertain whether an outgassing has taken place, and to what extent. In this case, it is possible to have recourse to the procedures described above in order to define threshold values that should not be exceeded, in order that the component 55 can be cleared for installation into an EUV lithography apparatus or one of the components thereof. After installation, the outgassing should be checked again in the manner already described.

It should be pointed out that the three method sequences described by way of example have been explained on the basis of an EUV lithography apparatus, but that the explanations can readily be applied to implementation in a projection or exposure system. For preparatory measurements, the method for measuring the outgassing can also be carried out in a vacuum system which is made available especially therefore and in which the outgassing from components is induced in the manner described above. This is appropriate, e.g., if the extent of outgassing is still completely unknown or an excessively high degree of outgassing is feared which, upon immediate incorporation, would cause an excessively high degree of contamination that can be removed with difficulty within, for example, an EUV lithography apparatus or the projection or illumination system thereof.

Thus, while there have been shown, described, and pointed out fundamental novel features of the invention as applied to several embodiments, it will be understood that various omissions, substitutions, and changes in the form and details of the illustrated embodiments, and in their operation, may be made by those skilled in the art without departing from the spirit and scope of the invention. Substitutions of elements from one embodiment to another are also fully intended and contemplated. The invention is defined solely with regard to the claims appended hereto, and equivalents of the recitations therein.

### REFERENCE SYMBOLS

10 EUV Lithography apparatus
11 Beam shaping system
12 EUV radiation source
13a Monochromator
13b Collimator
14 Illumination system
15 First mirror
16 Second mirror
17 Mask
18 Third mirror
19 Fourth Mirror
20 Projection system
21 Wafer
31 Residual gas analyzer
32 Electron gun
33 Residual gas analyzer
34 X-ray source
41 Residual gas particles
42 Electrons
43 Residual gas particles
44 Photons
50 Measurement station
51 Vacuum chamber
52 Stimulation unit
53 Residual gas analyzer
54 Holder
55 Component
101-115 Method steps
201-215 Method steps
301-311 Method steps

We claim:

1. A method for measuring an outgassing in a EUV lithography apparatus comprising:
activating a surface within the EUV lithography apparatus, so as to include the outgassing; and
analyzing a residual gas.

2. The method according to claim 1, wherein the outgassing is induced by irradiation with photons or by bombardment with one of charged and uncharged particles.

3. The method according to claim 2, wherein the outgassing is induced successively or simultaneously in different ways.

4. The method according to claim 1, further including the step of analyzing the residual gas before the activating step.

5. The method according to claim 1, further including the steps of:
defining, for different mass ranges of the residual gas constituents, different maximum partial pressures; and
comparing the measured partial pressures therewith.

6. The method according to claim 1, wherein for a specific chemical compound, the method further includes:
defining a maximum partial pressure;
recording a mass spectrum of the residual gas;
converting the highest-intensity peaks of the mass spectrum which can be assigned to the specific chemical compound into sub-partial pressures;
summing the sub-partial pressures; and
comparing the summed result with the defined maximum partial pressure.

7. The method according to claim 1, further including the step of carrying out the activation on a surface which is exposed to scattered radiation during operation of the EUV lithography apparatus.

8. The method according to claim 1, further including the step of starting the EUV lithography apparatus after the activating, inducing, and analyzing steps are performed.

9. The method according to claim 1, further including the steps of:
pausing the EUV lithography apparatus operation; and
then performing the activating, inducing, and analyzing steps.

10. The method according to claim 9, wherein the pausing step is performed after a part of the EUV lithography apparatus has been changed or after a new part has been installed.

11. The method according to claim 10, wherein before the changed or new part is installed a residual gas analysis is carried out with activation of its surfaces.

12. An EUV lithography apparatus comprising:
a stimulation unit comprised of at least one of an electron source, an ion source, a photon source, and a plasma source; and
a residual gas analyzer;
wherein the stimulation unit is configured to induce outgassing by exposing a surface within the EUV lithography apparatus to an output of the stimulation unit, and wherein the residual gas analyzer is configured to analyze the induced outgassing.

13. An illumination system for an EUV lithography apparatus comprising:
a stimulation unit comprised of at least one of an electron source, an ion source, a photon source, and a plasma source; and
a residual gas analyzer;
wherein the stimulation unit is configured to induce outgassing by exposing a surface within the EUV lithography apparatus to an output of the stimulation unit, and wherein the residual gas analyzer is configured to analyze the induced outgassing.

14. A projection system for an EUV lithography apparatus comprising:
a stimulation unit comprised of at least one of an electron source, an ion source, a photon source, and a plasma source; and
a residual gas analyzer;
wherein the stimulation unit is configured to induce outgassing by exposing a surface within the EUV lithography apparatus to an output of the stimulation unit, and wherein the residual gas analyzer is configured to analyze the induced outgassing.

15. A measurement setup for measuring the outgassing from components by analyzing the residual gas, comprising:
a stimulation unit comprised of at least one of an electron source, an ion source, a photon source, and a plasma source;
a residual gas analyzer; and
a vacuum chamber, wherein the stimulation unit and the residual gas analyzer are within the vacuum chamber;
wherein the stimulation unit is configured to induce outgassing by exposing a surface within the EUV lithography apparatus to an output of the stimulation unit, and wherein the residual gas analyzer is configured to analyze the induced outgassing.

16. A method for measuring the outgassing from components by analyzing a residual gas, that the method comprising:
activating, in a vacuum chamber, a surface of a component in order to induce outgassing, and
analyzing the residual gas in the vacuum chamber.

17. The method according to claim 16, wherein the residual gas is analyzed both before and after the surface activation.
